(19) United States
(12) Patent Application Publication
(10) Pub. No.: US 2014/0111075 A1
(43) Pub. Date: Apr. 24, 2014

(54) Electrical Housing with Laterally-Pivoting Hood

(71) Applicants: Jeffrey A. Schneider, Waukesha, WI (US); Jeramie A. Cooper, Sussex, WI (US)

(72) Inventors: Jeffrey A. Schneider, Waukesha, WI (US); Jeramie A. Cooper, Sussex, WI (US)

(21) Appl. No.: 13/657,417

(22) Filed: Oct. 22, 2012

(51) Int. Cl. H05K 5/03; A47B 88/18

(52) U.S. Cl. 312/326; 312/223.1

(57) ABSTRACT

A housing for electrical components may include a housing body which may include a first compartment for housing first electrical component(s) and an access panel. A hood may be pivotally coupled to the housing body at a first lateral side of the housing body such that the hood is rotatable about a generally vertical axis between (a) a closed position in which the hood and the access panel at least partially define a second compartment for housing second electrical component(s) coupled to the first electrical component(s) via one or more openings in the access panel, and (b) an open position providing access to the second electrical component(s). A locking system may be positioned at an askew angle to the hood and may lock the hood to the housing body at an upper portion of a lateral side of the hood. A tamper-resistant feature may also be included.

### TECHNICAL FIELD

The present application relates generally to housings for electrical components or devices (e.g., a transformer), and more particularly to an electrical housing with a laterally-pivoting hood.

### BACKGROUND

Certain electrical devices, e.g., electrical transformers, are typically maintained in locked housings. Some conventional housing designs include a difficult to access padlock and pentahead door bolt located at ground level, which tend to get covered by snow, dirt, or other objects. Also, some conventional housings include large, heavy hoods that are difficult to lift and close, causing ergonomic and safety issues with linemen. Further, certain existing door designs tend to pull the lineman in toward live electrical components.

### SUMMARY

In one aspect of the invention, a housing for electrical components may include a housing body and a laterally-pivoting hood. The housing body may include a first compartment for housing one or more first electrical components, and an access panel having one or more openings connecting the first compartment to an area outside the first compartment. The hood may be pivotally coupled to the housing body at a first lateral side of the housing body such that the hood is rotatable about a generally vertical axis of rotation between (a) a closed position in which the hood and the access panel of the housing body at least partially define a second compartment for housing one or more second electrical components coupled to the one or more first electrical components via the one or more openings in the access panel of the housing body, and (b) an open position providing access to the one or more second electrical components.

In another aspect of the invention, a housing for electrical components may include a housing body configured to house one or more electrical components; a hood pivotally coupled to the housing body at a first lateral side of the housing body such that in an installed orientation of the housing, the hood is rotatable about a generally vertical axis of rotation between an open position providing access to the one or more electrical components, and a closed position restricting access to the one or more electrical components; and a locking system including a hood locking element arranged on a second lateral side of the hood generally opposite the first lateral side of the hood pivotally coupled to the housing body.

### BRIEF DESCRIPTION OF THE DRAWINGS

FIG. 1 illustrates an example embodiment of an electrical component housing having a side-mounted, laterally-pivoting hood, with the hood in an open position.

FIG. 2 illustrates the example electrical component housing with the hood in an intermediate position.

FIG. 3 illustrates the example electrical component housing with the hood in a closed position.

FIGS. 4 and 5 illustrate a lower sill and engagement structures configured to receive corresponding lower engagement structures provided on the hood.

FIG. 6 illustrates lower engagement structures provided on the hood.

FIG. 7 is a front view of the example electrical component housing, showing the vertical alignment of lower engagement structures provided on the hood and the housing body.

FIGS. 8 and 9 illustrate upper engagement structures provided on a rear portion of the hood and a front portion of the housing body.

FIGS. 10-14 provide various views of the example electrical component housing, showing various aspects of a locking system for locking the hood in a closed position.

### DETAILED DESCRIPTION OF EXEMPLARY EMBODIMENTS

The invention may be better understood by reading the following description of non-limitative, exemplary embodiments with reference to the attached drawings wherein like parts of each of the figures are identified by the same reference characters.

Certain embodiments provide a housing for electrical components or devices (e.g., a transformer), which housing includes a laterally-pivoting or side-mounted hood. For example,

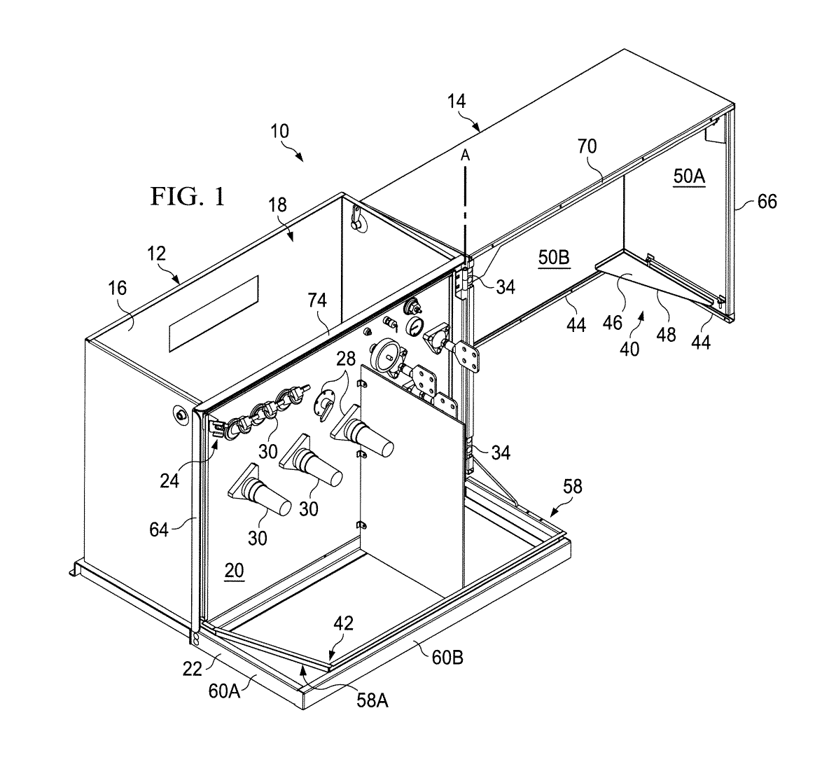

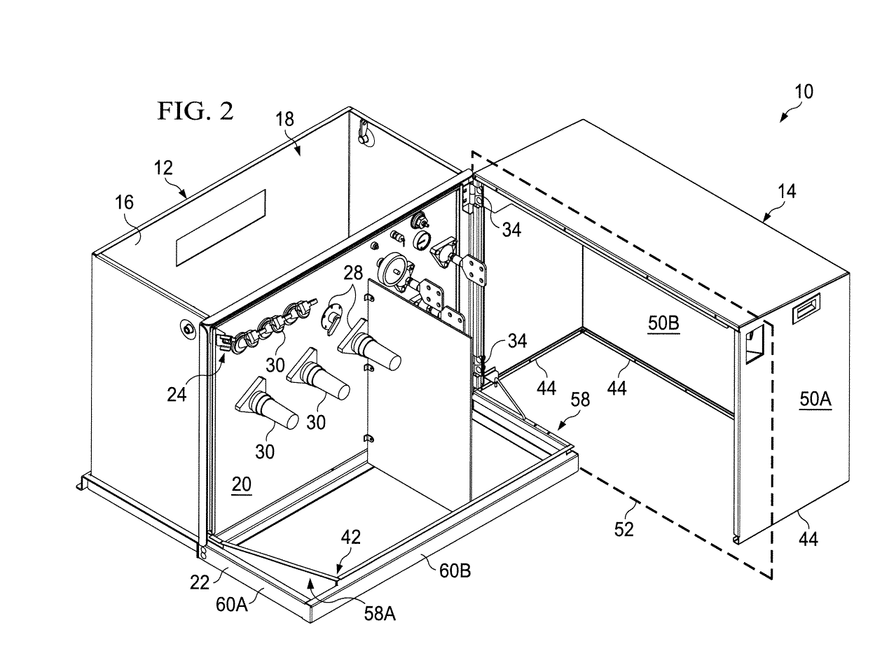

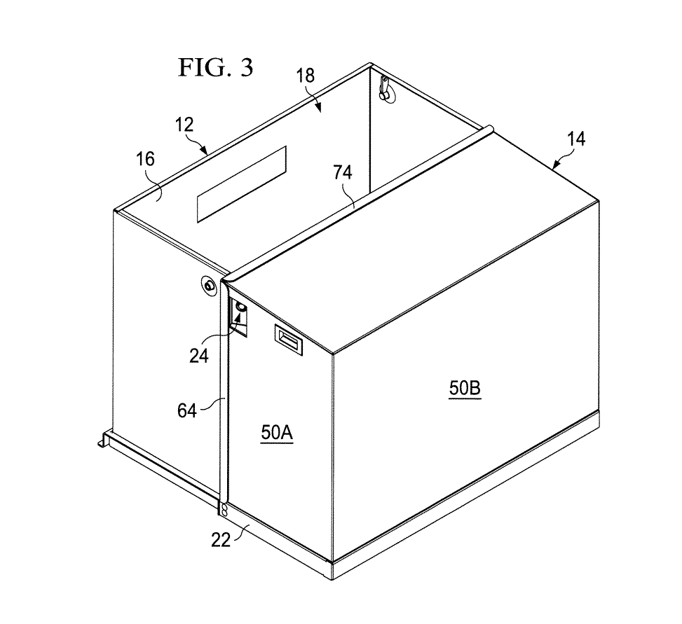

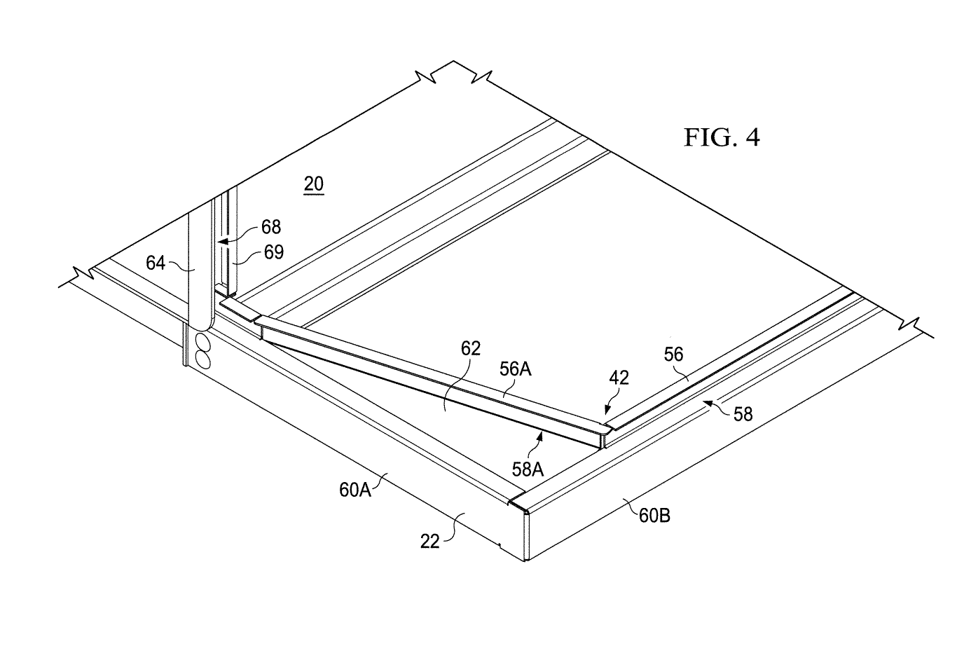

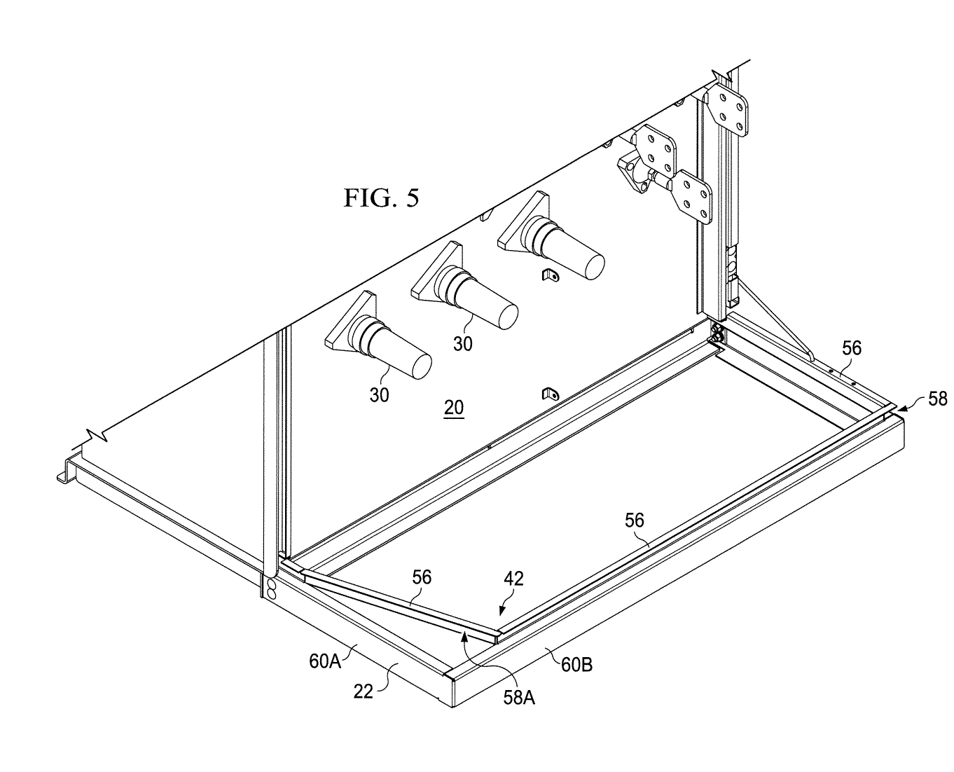

FIGS. 1-14 illustrate an electrical component housing 10 (e.g., transformer) having a housing body 12 and a laterally-pivoting hood 14, according to one example embodiment. More particularly, FIG. 1 illustrates the housing 10 with hood 14 in an open position, FIG. 2 illustrates the housing 10 with hood 14 in an intermediate position between the open position and a closed position, and FIG. 3 illustrates the housing 10 with hood 14 in the closed position, while FIGS. 4-14 illustrate various features of the example housing 10.

As shown in FIGS. 1-3, housing body 12 includes or defines a first compartment 16 for housing one or more first electrical components 18, an access panel 20, a sill 22 extending away from the first compartment 16, and portions of a locking system 24. First compartment 16 may be configured for housing any number and/or types of electrical components 18. For example, first compartment 16 may be configured for housing a transformer, e.g., a 1-phase or 3-phase transformer. In some embodiments, first compartment 16 is configured to be arranged as a sealed compartment at least partially filled with fluid, with first electrical component(s) 18 disposed within the fluid-filled compartment, e.g., to provide desired heat transfer or dissipation from first electrical component(s) 18. A top plate may be welded or otherwise secured to the open-ended top of housing body 12 to complete the compartment 16.

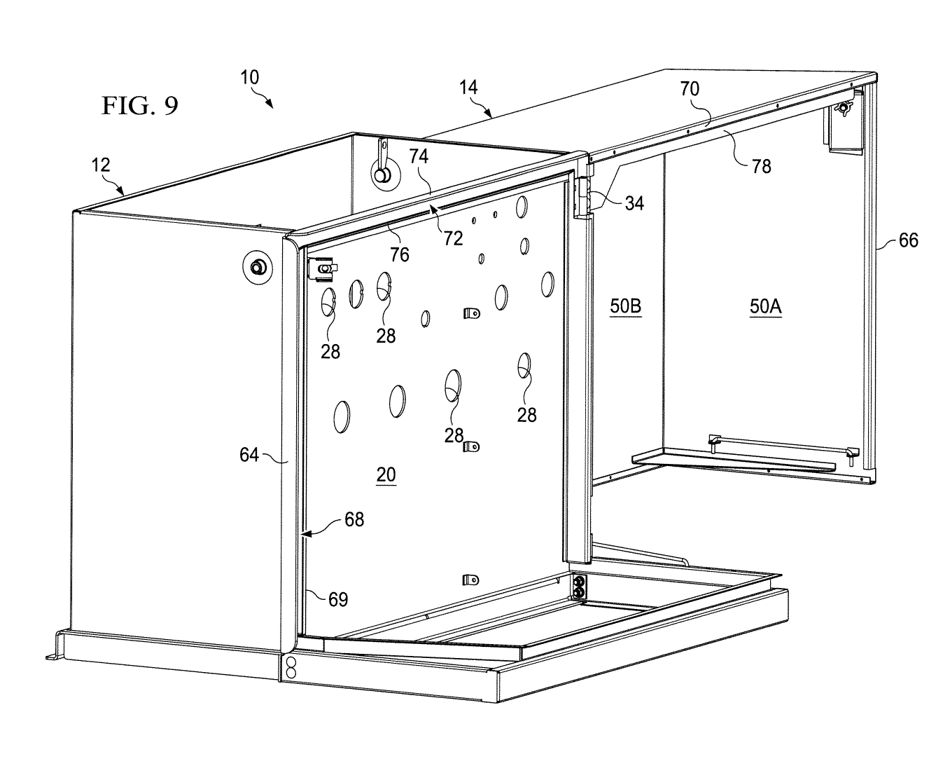

Access panel 20 acts as a partition between first compartment 16 (in this embodiment, a sealed compartment) and a second compartment 26 defined between hood 14 and access panel 20 when hood 14 is in the closed position (i.e., the position of FIG. 3). Access panel 20 may include one or more bushings or openings 28 that allow access to first compartment 16 (openings 28 are shown in FIG. 9). Thus, one or more second electrical components 30 located at least partially within the second compartment 26 may be coupled to the first electrical component(s) 18 in the first compartment 16 via the opening(s) 28 in access panel 20. Each opening 28 may be sealed, e.g., by a gasket or other sealing element, to prevent fluid communication from the first compartment 16 into the second compartment 26. Second electrical component(s) 30 may include any suitable components or devices, e.g., devices for monitoring and/or controlling operational aspects of first electrical component(s) 18 (e.g., a transformer).

Sill 22 may be configured to receive and engage with hood 14, e.g., to provide a secure and tamper-resistant connection between hood 14 and housing body 12, as discussed below in greater detail. Sill 22 may have an open bottom area within a sill perimeter, as shown in the embodiment of FIG. 1, or may include a solid bottom.

As shown in FIGS. 1-3, hood 14 may be pivotally coupled to the housing body 12 at a first lateral side of the housing body 12 such that in an installed orientation of housing 10, hood 14 is rotatable about a generally vertical axis of rotation A between on open position (FIG. 1) and a closed position (FIG. 3). The open position of hood 14 provides manual access to the second electrical component(s) 30, e.g., allowing a technician or other operator to monitor, control, or otherwise interface with first electrical component(s) 18 housed in first compartment 16. In the closed position of hood 14, hood 14 and access panel 20 define the second compartment 26 in which second electrical component(s) 30 are housed.

Hood 14 may be pivotally coupled to housing body 12 in any suitable manner. For example, hood 14 may be coupled to housing body 12 by one or more vertically-oriented hinges 34 coupled to housing body 12 near a lateral side of access panel 20. Although hood 14 is shown mounted on the right side of housing body 12, in other embodiments hood 14 is mounted on the left side in a similar manner.

Hood 14 and sill 22 may include any suitable structures to provide a secure and tamper-resistant engagement between hood 14 and housing body 12, when hood 14 is positioned in the closed position. For example, as shown in FIGS. 1, 2, 4, 5, and 6, hood 14 may include a first engagement structure 40 proximate a bottom edge of hood 14, and sill 22 may include a second engagement structure 42 configured to engage with the first engagement structure 40 of hood 14, in the closed position of hood 14. First engagement structure 40 and second engagement structure 42 may provide any suitable physical engagement, e.g., a tongue-and-groove or flange-and-groove engagement, or any other type of physical engagement.

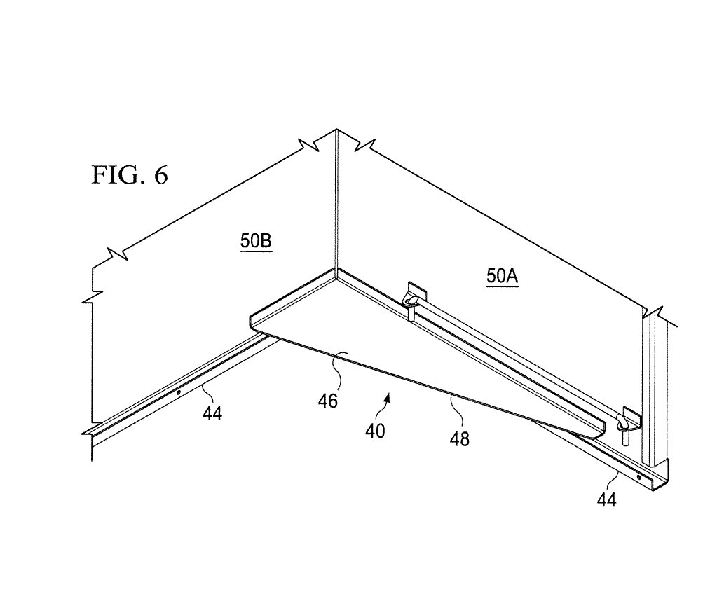

In the illustrated embodiment, first engagement structure 40 includes a U-shaped or J-shaped flange 44 extending along all three sides of the lower perimeter of hood 14, and a web 46 having a leading edge 48 extending between a first lateral side 50A and a front side 50B of hood 14 in an askew manner (in this case, diagonally) with respect to the rear plane 52 of hood 14 (shown in FIG. 2). Details of flange 44 and web 46 are best shown in FIG. 6.

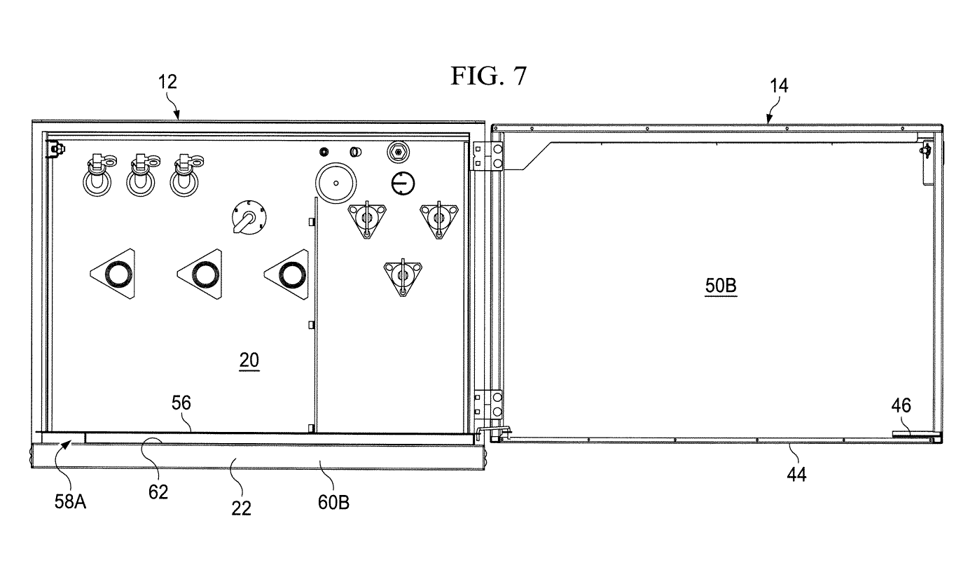

Second engagement structure 42 of sill 22 includes flanges 56 that define a groove 58 extending along all three sides of the perimeter of sill 22. As shown in FIGS. 1, 2, 4, and 5, flanges 56A that define a groove portion 58A at the side of sill 22 generally opposite the pivoting connection of hood 14 extends between a first lateral side 60A and a front side 60B of sill 22 in an askew manner (in this case, diagonally) with respect to access panel 20. When hood 14 is moved to the closed position, the askew groove portion 58A is configured to receive the askew leading edge 48 of web 46 provided on hood 14. Further, each side or portion of U-shaped or J-shaped flange 44 of hood 14 is received in a corresponding side or portion of groove 58 extending around sill 22, except for the portion of flange 44 below web 46, which may rest on or just above an upper surface 62 of sill 22 but laterally removed the askew groove potion 58A. The engagement of flange 44 and web 46 of hood 14 with groove 58 and upper surface 62 of sill 22 is best understood in view of FIGS. 1, 4, 5, and 6 collectively. In addition, FIG. 7 provides a front view of housing 10 with hood 14 in an open position, which illustrates the relative vertical alignment of flange 44, web 46, and groove 58. In particular, the figure shows that in the area of web 46, both flange 44 and web 46 are sized and arranged to fit within the vertical dimension of groove 58, i.e., between the upper surface 62 of sill 22 and top flange 56.

As used herein, the term “askew” means non-parallel and non-perpendicular with respect to the respective element of housing 10. For example, an askew element may extend diagonally or in a curved manner with respect to the respective element of housing 10. Thus, for example, leading edge 48 of web 46 may extend diagonally or in a curved manner with respect to the rear plane 52 of hood 14, and groove portion 58A may extend diagonally or in a curved manner with respect to access panel 20.

The askew alignment of web 46 and groove portion 58A is designed to prevent interference between the first engagement structure 40 and second engagement structure 42 (specifically between flange 44 and flanges 56) during movement of hood 14 between the closed and open positions. That is, if flanges 44 and 56 simply extended around the rectangular outer perimeter of hood 14 and sill 22, respectively, the outer corner of flanges 56 (i.e., opposite the hinged connection of hood 14) would prevent the outer corner of flange 44 (i.e., opposite the hinged connection of hood 14) from passing by, thus preventing hood 14 from swinging between open and closed positions (in either direction).

The interaction between first and second engagement structures 40 and 42 may provide a tamper-resistant and/or weather-resistant engagement. For example, the engagement of flange 44 and web 56 within groove 58 provides a labyrinth structure that may prevent an unauthorized person from sliding a wire or tool (e.g., a #14 copper wire, screwdriver, or other tool or object) between the hood 14 and sill 22, e.g., in an attempt to tamper with electronic components 30. In addition, sill 22 acts to maintain hood 14 elevated from the ground or floor, which may reduce the likelihood of hood 14 being blocked, e.g., by snow, dirt, rocks, or other objects.

In addition to the engagement between first and second engagement structures 40 and 42 at lower portions of hood 14 and housing body 12 (specifically, sill 22), hood 14 and housing body 12 may also be configured to engage at upper portions and/or at the locking side of the enclosure, e.g., to provide a tamper-resistant and/or weather-resistant coupling in the closed position of hood 14. For example, as shown in FIG. 1, housing body 12 may include a top flange 74 and/or a lateral side flange 64 configured to cover or otherwise engage with a top flange 70 and/or a lateral side flange 66 provided on hood 14, when hood 14 is moved to the closed position.

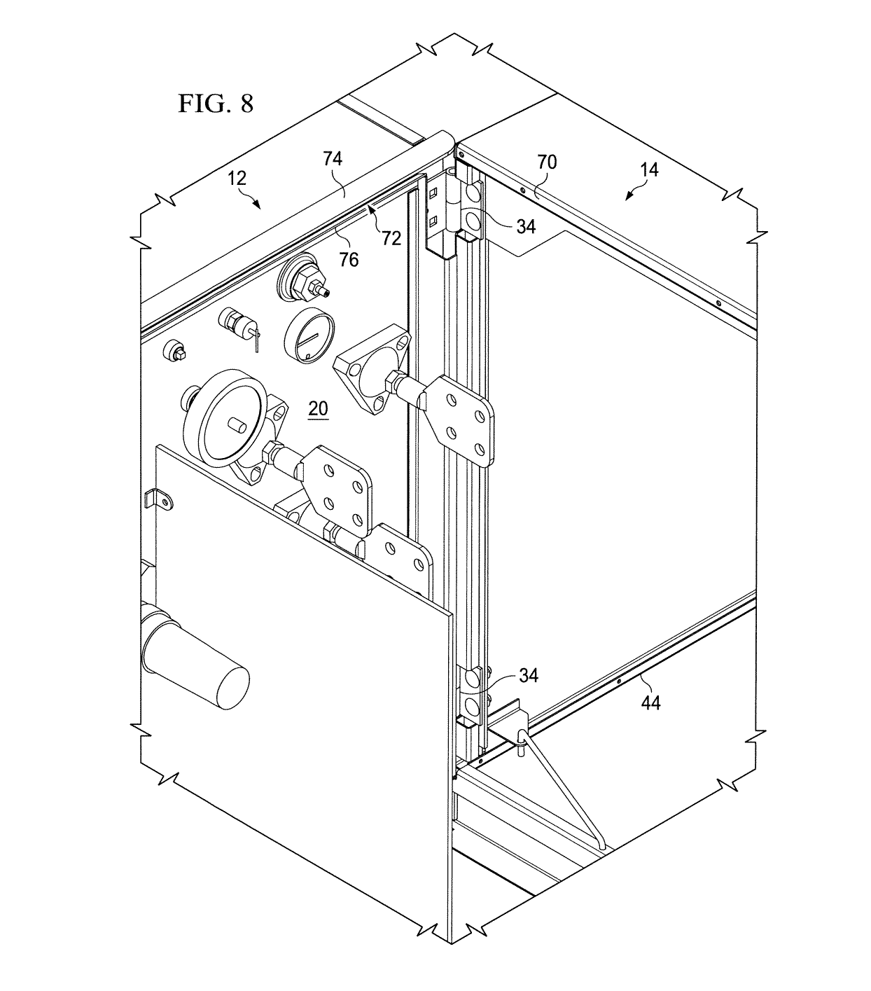

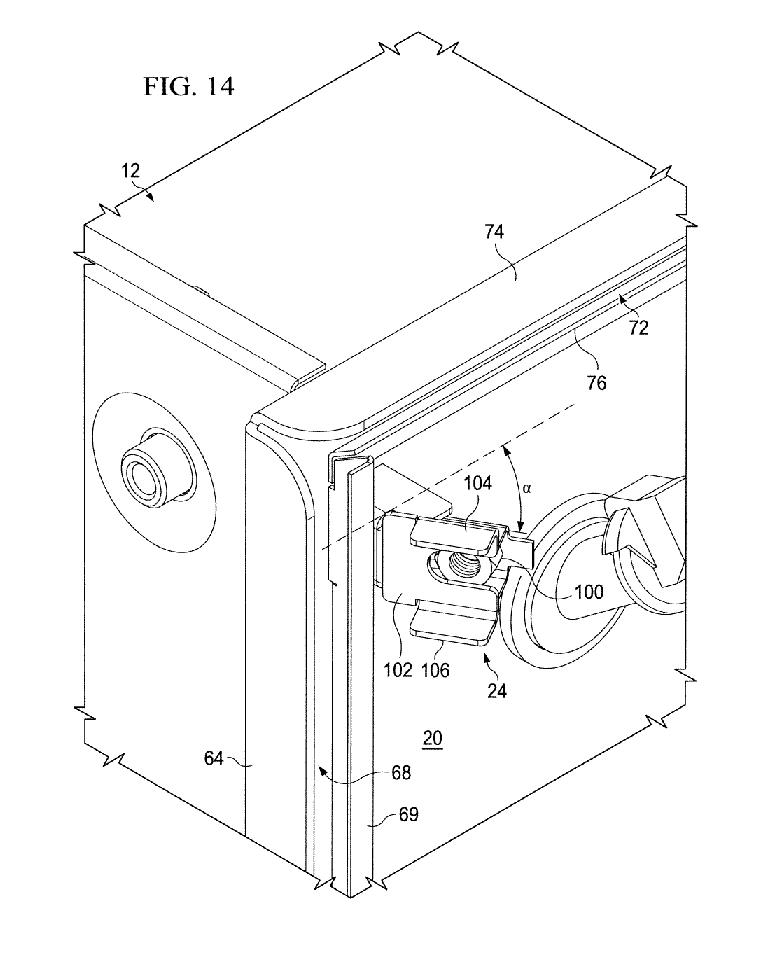

FIGS. 8 and 9 illustrate components for the physical engagement between hood 14 and housing body 12 at the upper portion of such components. (Note that electronic components 30 are not shown in FIG. 9, for illustrative purposes.) Hood 14 may include a top flange 70 extending in the rear plane 52 of hood 14. As shown in FIG. 9, housing body 12 may include a groove or recess 72 defined between a first top flange 74 and a second top flange 76, which recess 72 is configured to receive the top flange 70 of hood 14. Recess 72 and flanges 74 and 76 are also shown in FIG. 14. The engagement between top flange 70 and recess 72 may provide a labyrinth structure that may prevent an unauthorized person from sliding a wire or tool (e.g., a #14 copper wire, screwdriver, or other tool or object) between the hood 14 and housing body 12, e.g., in an attempt to tamper with electronic components 30. Also, as shown, second top flange 76 may be angled, tapered, or otherwise configured to guide water away from electronic components 30 in second compartment 26, this providing a water-resistant arrangement.

Also, as shown, housing body 12 may include a groove or recess 68 defined between an outer lateral flange 64 and an inner flange 69, which recess 68 is configured to receive the lateral flange 66 of hood 14. Recess 68 and flanges 64 and 69 are also shown in FIG. 14. The engagement between top flange 66 and recess 68 may provide a labyrinth structure that may prevent an unauthorized person from sliding a wire or tool (e.g., a #14 copper wire, screwdriver, or other tool or object) between the hood 14 and housing body 12, e.g., in an attempt to tamper with electronic components 30.

Hood 14 may also include a structural stiffener 78 extending across the top rear side of hood 14, which may prevent hood 14 from sagging or otherwise losing its shape. Stiffener 78 may be slightly set back from top flange 70 such that it is does not interfere with second top flange 76 on housing body 12.

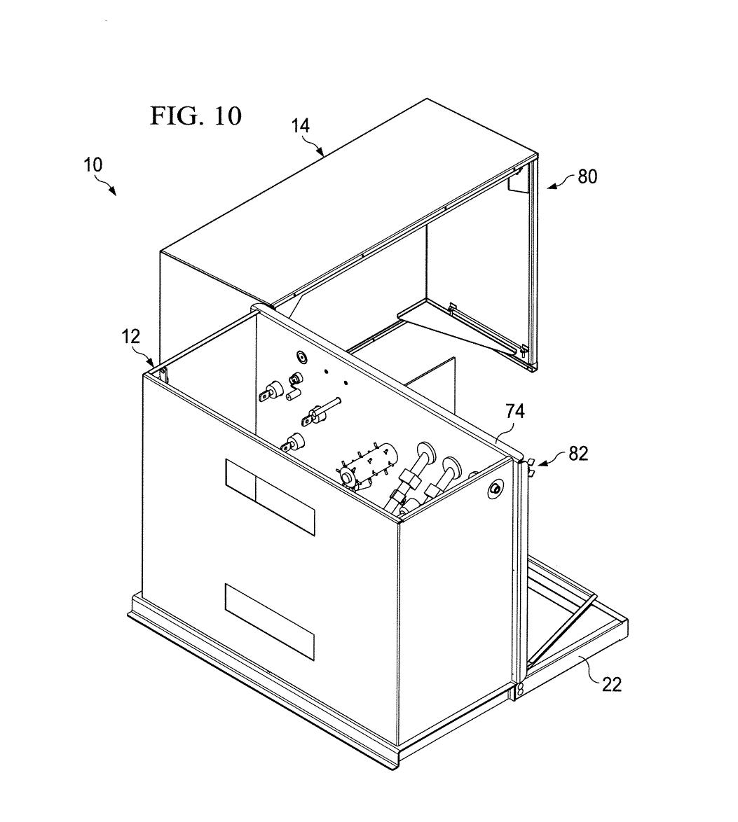

FIGS. 10-14 illustrate aspects of a locking system 24 for locking hood 14 in the closed position. As shown in FIG. 10, locking system 24 includes a first locking portion 80 on hood 14 configured to interact with a second locking portion 82 on housing body 12. In this embodiment, locking system 24 is arranged at an upper portion of hood 14 at the lateral side 50A of hood 14 opposite the hinged connection. In other embodiments, locking system 24 may be located at a lower portion of lateral side 50A. In other embodiments, locking system 24 may include multiple locking elements located along lateral side 50A, e.g., located at upper, central, and/or lower portions of side 50A. In still other embodiments, locking system 24 may be located at the front side 50B of hood 14. In still other embodiments, locking system 24 may be located on the top surface of hood 14.

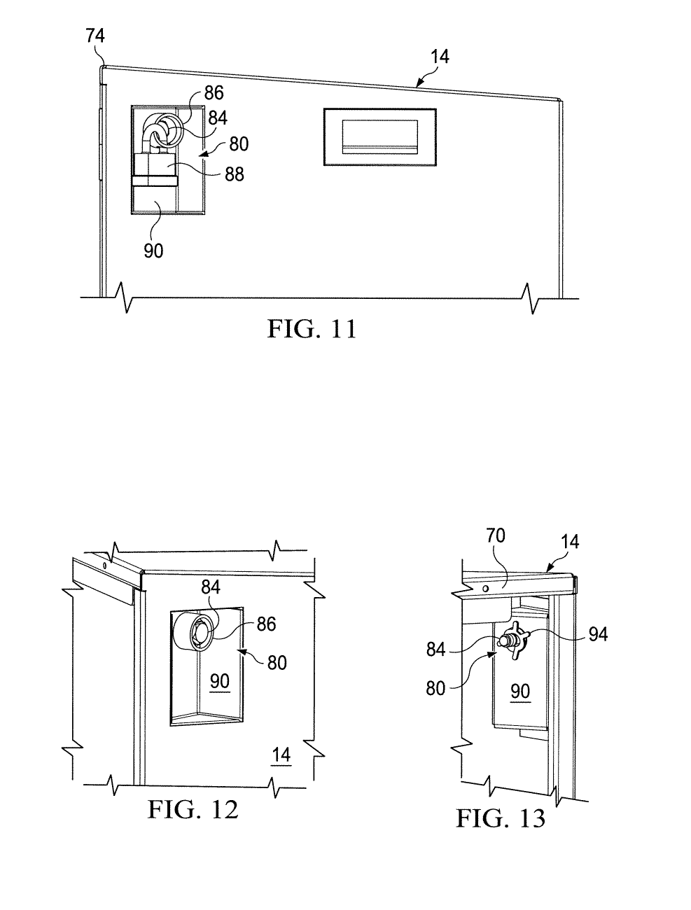

FIGS. 11 and 12 illustrate a left side view and a perspective view, respectively, of hood 14 in a closed and locked position (the portion of housing body 12 corresponding to first compartment 16 is not shown, for illustrative purposes), in particular showing first locking portion 80 of hood 14 from the outside. As shown, first locking portion 80 includes a hood locking element (locking bolt) 84 positioned within a recess formed by a guard housing 86, both of which are arranged in a recess 90 formed in side wall 50A of hood 14. Hood locking element 84 and recess 90 are arranged askew from side wall 50A and from rear plane 52 of hood 14 to may provide desired directional locking forces, as discussed below. An access lock 88 (shown in FIG. 11) may be provided to regulate access to hood locking element 84 for operation of hood locking element 84. For example, access lock 88 may be a padlock extending through guard housing 86 to prevent a tool (e.g., wrench) from accessing and operating hood locking element 84.

FIG. 13 illustrates first locking portion 80 from the inside of hood 14. As shown, hood locking element 84 extends to the inside of hood 14, and may be secured to side wall 50A by a retention flange or washer 94. First locking portion 80 may also include a spring that biases hood locking element 84 longitudinally.

FIG. 14 illustrates second locking portion 82 on housing body 12. Second locking portion 82 may include a captive nut system including a nut 100 supported in a nut housing 102. Nut housing 102 includes a pair of flanges 104 and 106 configured to receive retention flange 94 between flanges 104 and 106, e.g., for alignment of first locking portion 80 with second locking portion 82. Nut housing 102 is arranged to align nut 100 askew from access panel 20, such that the opening in nut 10 aligns with locking bolt 84 (also arranged askew, as discussed above) when hood 14 is closed. Thus, nut 100 may be aligned at any suitable angle α between 0 and 90 degrees (non-inclusive) with respect to access panel 20. For example, angle α may be between 10 and 80 degrees. In some embodiments, angle α is between 20 and 70 degrees. In particular embodiments, angle α is between 30 and 60 degrees. The askew alignment of bolt 84 and nut 100 (with respect to the hood 14 and housing body 12, respectively) may provide desired directional locking forces. For example, the alignment of bolt 84 and nut 100 may provide that tightening of hood locking element 84 in nut 100 biases the lateral side 50a of hood 14 both (a) rearward toward access panel 20 and (b) laterally toward opposing lateral side of hood 14. These directional forces may help secure hood 14 on sill 22, and may resist hood 14 being pulled or pried away from housing body 12 and/or sill 22.

What is claimed is:

1. A housing for electrical components, comprising:
a housing body comprising:
a first compartment for housing one or more first electrical components; and
an access panel having one or more openings connecting the first compartment to an area outside of the first compartment;
a hood pivotally coupled to the housing body at a first lateral side of the housing body such that in an installed orientation of the housing, the hood is rotatable about a generally vertical axis of rotation between:
a closed position in which the hood and the access panel of the housing body at least partially define a second compartment for housing one or more second electrical components coupled to the one or more first electrical components via the one or more openings in the access panel of the housing body; and
an open position providing access to the one or more second electrical components.

2. The housing of claim 1, wherein the hood is pivotally coupled to the housing body by one or more generally vertically-oriented hinges coupled to the housing body proximate a lateral side of the access panel.

3. The housing of claim 1, wherein:
the hood comprises a first engagement structure proximate a bottom edge of the hood; and
the housing body comprises a sill extending away from the first compartment, the sill comprising a second engagement structure configured to engage with the first engagement structure of the hood in the closed position of the hood.

4. The housing of claim 3, wherein the engagement between the first and second engagement structures comprises a flange-and-groove engagement.

5. The housing of claim 3, wherein:
a bottom edge of the hood defines a lower hood perimeter having at least two sides;
the sill defines a sill perimeter having at least two sides and corresponding generally to the lower hood perimeter;
the first engagement structure of the hood extends along the at least two sides of the lower hood perimeter; and
the second engagement structure of the sill extends along the at least two sides of the sill perimeter.

6. The housing of claim 3, wherein:
the hood defines a rear plane that extends generally parallel with the access panel in the closed position of the hood;
the first engagement structure of the hood comprises a first engagement portion extending askew with respect to the rear plane of the hood;
the second engagement structure of the sill comprises a second engagement portion extending askew with respect to the access panel, the second engagement portion being configured to engage with the first engagement portion in the closed position of the hood;
wherein the askew alignment of each of the first and second engagement portions prevents interference between the first and second engagement structures during movement of the hood between the closed and open positions.

7. The housing of claim 6, wherein the first engagement portion of the first engagement structure of the hood comprises a web extending between two sides of the hood in an askew direction with respect to the rear plane of the hood.

8. The housing of claim 1, comprising a locking system including a hood locking element arranged on a second lateral side of the hood generally opposite the first lateral side of the hood pivotally coupled to the housing body.

9. The housing of claim 8, wherein the hood locking element is arranged at an upper portion of the second lateral side of the hood.

10. The housing of claim 8, wherein the hood locking element is arranged at a lower portion of the second lateral side of the hood.

11. The housing of claim 8, wherein the hood locking element is aligned askew with respect to the second lateral side of the hood such that tightening of the hood locking element in the closed position of the hood biases the second lateral side of the hood toward the access panel.

12. The housing of claim 11, wherein the locking system further comprises a housing body locking element aligned askew with respect to the access panel.

13. The housing of claim 12, wherein the housing body locking element comprises a captive nut aligned askew with respect to the access panel.

14. The housing of claim 8, wherein the hood locking element is located in a recessed portion of the second lateral side of the hood.

15. The housing of claim 1, comprising a locking system including a hood locking element arranged at an upper area of the hood.

16. The housing of claim 1, wherein:
the hood comprises a top flange at a rear edge of the hood; and
the housing body comprises at least one flange near the access panel and configured to engage with the top flange of the hood in the closed position of the hood.

17. The housing of claim 1, wherein:
the hood comprises a lateral side flange at a lateral side of the hood generally opposite the first lateral side of the hood pivotally coupled to the housing body; and
the housing body comprises at least one flange near a lateral side of the access panel and configured to engage with the lateral side flange of the hood in the closed position of the hood.

18. The housing of claim 1, wherein the first compartment is a sealed compartment configured for housing the one or more first electrical components in fluid.

19. The housing of claim 18, wherein the one or more openings in the access panel are sealed to prevent fluid ingress from the first compartment into the second compartment via the one or more openings.

20. A housing for electrical components, comprising:
a housing body configured to house one or more electrical components;
a hood pivotally coupled to the housing body at a first lateral side of the housing body such that in an installed orientation of the housing, the hood is rotatable about a generally vertical axis of rotation between:
an open position providing access to the one or more electrical components; and
a closed position restricting access to the one or more electrical components;
a locking system including a hood locking element arranged on a second lateral side of the hood generally opposite the first lateral side of the hood pivotally coupled to the housing body.

21. The housing of claim 20, wherein the hood locking element is aligned askew with respect to the second lateral side of the hood such that tightening of the hood locking element in the closed position of the hood biases the second lateral side of the hood toward the housing body and toward the first lateral side of the housing body.
